(19) United States
(12) Patent Application Publication
(10) Pub. No.: US 2002/0142627 A1
(43) Pub. Date: Oct. 3, 2002

(54) Connection structure between terminal and flexible printed circuit body and auxiliary machine module

(75) Inventor: Isao Kameyama, Shizuoka (JP)

Correspondence Address: ARMSTRONG,WESTERMAN & HATTORI, LLP, 1725 K STREET, NW., SUITE 1000, WASHINGTON, DC, 20006, US

(73) Assignee: Yazaki Corporation, Tokyo (JP)

(21) Appl. No.: 10/106,376

(22) Filed: Mar. 27, 2002

(30) Foreign Application Priority Data
Mar. 28, 2001 (JP) 2001-93234

(51) Int. Cl. H05K 1/00

(52) U.S. Cl. 439/67

(57) ABSTRACT

A connection structure between a terminal and a flexible printed circuit body is provided, by which without soldering the terminal can excellently be electro-conductively connected to the flexible printed circuit body by a holding power generated when the terminal is inserted into a base. The connection structure includes: a base including a mounting hole for receiving a terminal and a locking hollow for fixing the terminal; a flexible printed circuit body including a circuit conductor; and the terminal including a first locking portion engaging with the locking hollow and a second locking portion fixed to the base putting the flexible printed circuit body therebetween, wherein the terminal is inserted in the mounting hole through the circuit conductor so as to be electro-conductively connected to the circuit conductor.

### BACKGROUND OF THE INVENTION

(1) Field of the Invention

The present invention relates to a connection structure between a terminal and a flexible printed circuit body adaptable to the assembly and disassembly operation, in which a terminal and a flexible printed circuit body can be electro-conductively (i.e. electrically) connected to each other. Relating to such a structure, the present invention also relates to an auxiliary machine module, whereby the auxiliary machine module, consisting of an auxiliary machine such as a CCD camera to be mounted on a vehicle, a board for the auxiliary machine and a case, can be detachably connected to a mating component by using a connector.

(2) Description of the Related Art

In the following, prior art will be explained with reference to FIG. 7.

FIG. 7 is an enlarged perspective view illustrating a conventional connection structure between a terminal and a flexible printed circuit body and illustrating an intermediate component as an example. In detail, the intermediate component 5′, that is, the intermediate connector board 5′ consists of a molded resin part 6′, flexible printed circuit body (abbreviated as FPC) 7, and a plurality of male terminals 8z, each having a round pin-shape.

The molded resin part 6′ is a molded resin body, in which a first base 6a′, a second base 6b′ and a board 6c′ are integrally formed. The first base 6a′ and the second base 6b′ are projectingly formed on the board 6c′. A hole 6d for mounting the terminal, which is fit to the male terminal 8z when the male terminal 8z is press fit thereinto, is provided at three positions for each of the first base 6a′ and second base 6b′. The hole 6d is formed passing through the portion of the first base 6a′ or the second base 6b′.

At the bottom of the first 6a′, an insertion hole 6f for inserting the flexible printed circuit body (FPC) 7 thereinto is formed passing through the board 6c′. The board 6c′ has a rectangular flat plate-shape. In order to fix the molded resin part 6′ to a mount of a mating part, two holes 6g for mounting the board 6c′ are provided at specific positions of the board 6c′.

As for the flexible printed circuit body (FPC) 7 to be mounted on the molded resin part 6′, three circuit conductors 7a made of metal foil such as copper foil are printed in parallel on an insulating sheet 7b, on which a protection layer 7c is provided. The flexible printed circuit body 7 thus constructed is a flexible printed wiring plate.

The circuit conductor 7a is covered by the insulating sheet 7b and protection layer 7c so that the circuit conductor 7a is prevented from coming into contact with the other parts, that is, for preventing a short circuit from occurring. In response to each hole 6d, each end 7e of the circuit conductor 7a is provided with a through hole 7d for receiving the male terminal 8z having a round pin-shape.

The male terminal 8z having a cylindrical shape includes a body 8b, front end 8c and rear end 8d. A part of the body 8b serves as an electric contact 8a, which comes into contact with a mating female terminal.

Each male terminal 8z is inserted into the hole 6d. In order to make the soldering between the rear end 8d of each male terminal 8z and the circuit conductor 7a easily be performed, each male terminal 8z is press fit into the hole 6d in such a manner that the rear end 8d is a little pushed out from the surface of the first and second bases 6a′ and 6b′ from the corresponding hole 6d.

Each through hole 7d receives the corresponding rear end 8d of the male terminal 8z, which is inserted into the hole 6d. The circuit body 7 is inserted through the insertion hole 6f from the bottom of the first base 6a′.

Thus, the circuit body 7 is mounted on the specific position of the molded resin part 6′.

Thereafter, each end 7e of the circuit conductor 7a, the corresponding through hole 7d and the corresponding rear end 8d of the male terminal 8z mounted in the base 6a′ are soldered with each other, thereby they are electrically connected to each other through the solder SD.

Thus, the assembly is carried out so that one circuit conductor 7a of the circuit body 7 can be electrically connected to the other circuit conductor 7a of the circuit body 7.

In the following, the prior art will be briefly explained.

In Japanese Patent Application Laid-Open No. H4-28116, disclosed is a structure of a flexible printed cable having a through hole with a projection provided at an electrode of the cable as to a flexible printed cable (so-called FPC) having a electrode.

In Japanese Patent Application Laid-Open No. H5-110246, disclosed is a connection method and electrode terminal-mounting method of a flat conductor wiring plate, by which the connection work is made easily be done by decreasing the number of steps and an excellent electric connection reliability can be secured.

In Japanese Patent Application Laid-Open No. H8-203580, disclosed is a secure and excellent conducting structure of a flexible printed wiring plate (so-called FPC) through a fixing member.

However, with the electric connection described above with reference to FIG. 7, when a pitch between each male terminal 8z provided at a first or second electric connection part 31′ or 32′, that is, a first or second connector body 31′ or 32′ becomes narrow, even if one tries to connect the rear end 8d of the male terminal 8z to the circuit body 7 by soldering, a correct soldering is hard to do since there is secured only a very small gap between each part to be soldered.

Recently, in terms of environmental conservation, lead-free solder has been widely employed, which requires higher temperature when applied than that for a conventional solder material.

When the circuit conductor 7a of the circuit body 7 is tried to be connected to the rear end 8d of the male terminal 8z by using such a lead-free solder material, since the insulating sheet 7b of the circuit body 7 cannot maintain a specific shape and dimensional accuracy thereof due to the deterioration at high temperature, therefore the connection therebetween to secure an electrical conduction as the need arises has been difficult so far.

### SUMMARY OF THE INVENTION

It is therefore an objective of the present invention to solve the above problem and to provide a connection structure between a terminal and a flexible printed circuit body, by which a terminal is fixed to a base by a holding power with two locking parts provided at the terminal without soldering when the terminal is mounted to the base, and the terminal can excellently be electro-conductively connected to the flexible printed circuit body.

Another objective of the present invention is to provide an auxiliary machine module, by which the auxiliary machine module, consisting of an auxiliary machine such as a camera, a board on which the auxiliary machine is mounted and a case, can easily be detachably connected to a mating component to be connected to the auxiliary machine module by using a connector, and the assembly or disassembly operation can be easily carried out when the auxiliary machine module is disassembled or assembled.

In order to attain the above objective, the present invention is to provide a connection structure between a terminal and a flexible printed circuit body comprising:

a base including a mounting hole for receiving a terminal and a locking hollow for fixing the terminal;

a flexible printed circuit body including a circuit conductor; and

the terminal including a first locking portion engaging with the locking hollow and a second locking portion fixed to the base putting the flexible printed circuit body therebetween, wherein the terminal is inserted in the mounting hole through the circuit conductor so as to be electro-conductively connected to the circuit conductor.

Preferably, the first locking portion abuts against the locking hollow formed on the circumference of the mounting hole while the second locking portion abuts against the circuit conductor so that the terminal is fixed in the base.

Preferably, the first locking portion is a pair of projections while the second locking portion is a bent portion having an S-shape.

The present invention is also to provide an auxiliary machine module comprising:

an auxiliary machine board which includes a terminal and is mounted on an auxiliary machine;

an intermediate component including: a first electric joint having a first terminal and a first base, in which the first terminal having first and second locking portions is mounted to the first base; a second electric joint having a second terminal and a second base, in which the second terminal having the first and second locking portions is mounted to the second base; and a flexible printed circuit body in which a circuit conductor connects the first terminal of the first electric joint to the second terminal of the second electric joint; and

a case,

wherein a connector housing is formed in the case to receive the first electric joint, the first electric joint is mounted in the connector housing so that a connector is formed in the case, and the auxiliary machine board is mounted to the case so that the terminal of the auxiliary machine board is coupled with the second terminal of the second electric joint.

Preferably, a mating connector including a terminal is coupled with the connector formed in the case having the first terminal so as to make an electrical connection.

Preferably, the auxiliary machine is a camera to be mounted on a motor vehicle.

### BRIEF DESCRIPTION OF THE DRAWINGS

FIG. 1 is an enlarged perspective view illustrating a connection structure between a terminal and a flexible printed circuit body according to the present invention;

FIG. 2 is a longitudinal cross sectional view illustrating a connection structure between a terminal and a flexible printed circuit body;

Each of FIGS. 3A-3C is an enlarged perspective view illustrating an example of a terminal employed in another preferred embodiment;

FIG. 4 is an enlarged perspective view illustrating an example of a terminal employed in another preferred embodiment;

FIG. 5 is an exploded perspective view illustrating an auxiliary machine module according to the present invention;

FIG. 6 is an enlarged perspective view illustrating a mating connector; and

FIG. 7 is an enlarged perspective view illustrating a conventional connection structure between a terminal and a flexible printed circuit body.

### DESCRIPTION OF THE PREFERRED EMBODIMENTS

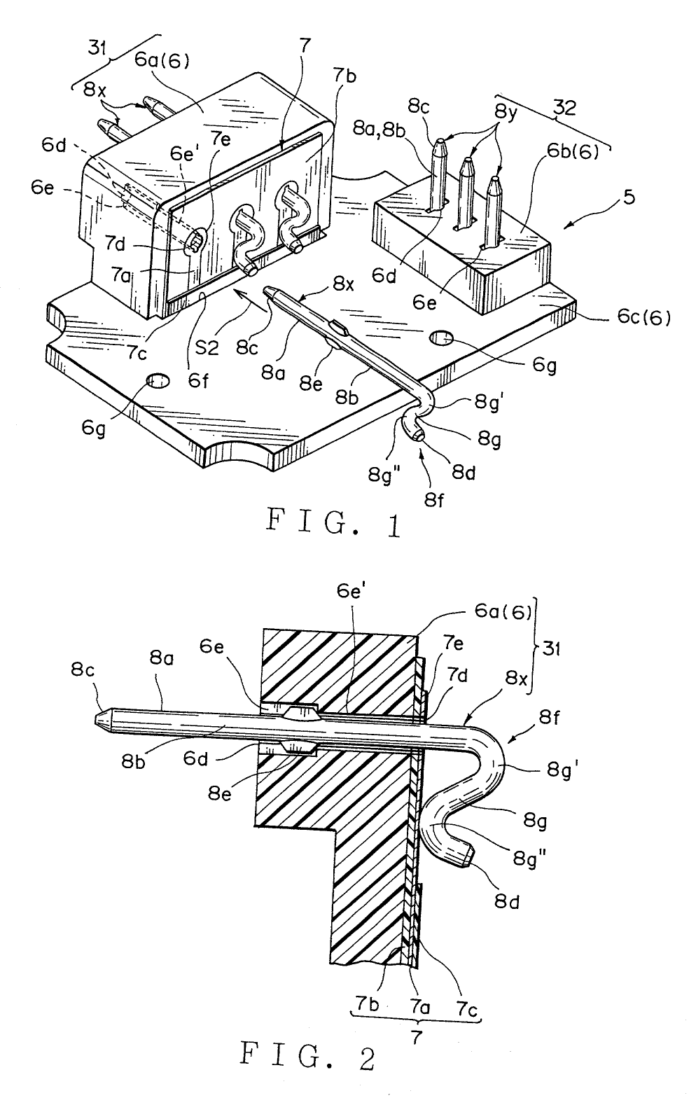

In the following, a preferred embodiment of a connection structure between a terminal and a flexible printed circuit body and that of an auxiliary machine module according to the present invention will be explained with reference to FIGS. 1-6. As an example of the auxiliary machine module, a camera module Z will be explained. The same abbreviation numeral is used for each of the following elements which has the same name as that in the conventional example as described above, and accordingly the explanation thereof is omitted.

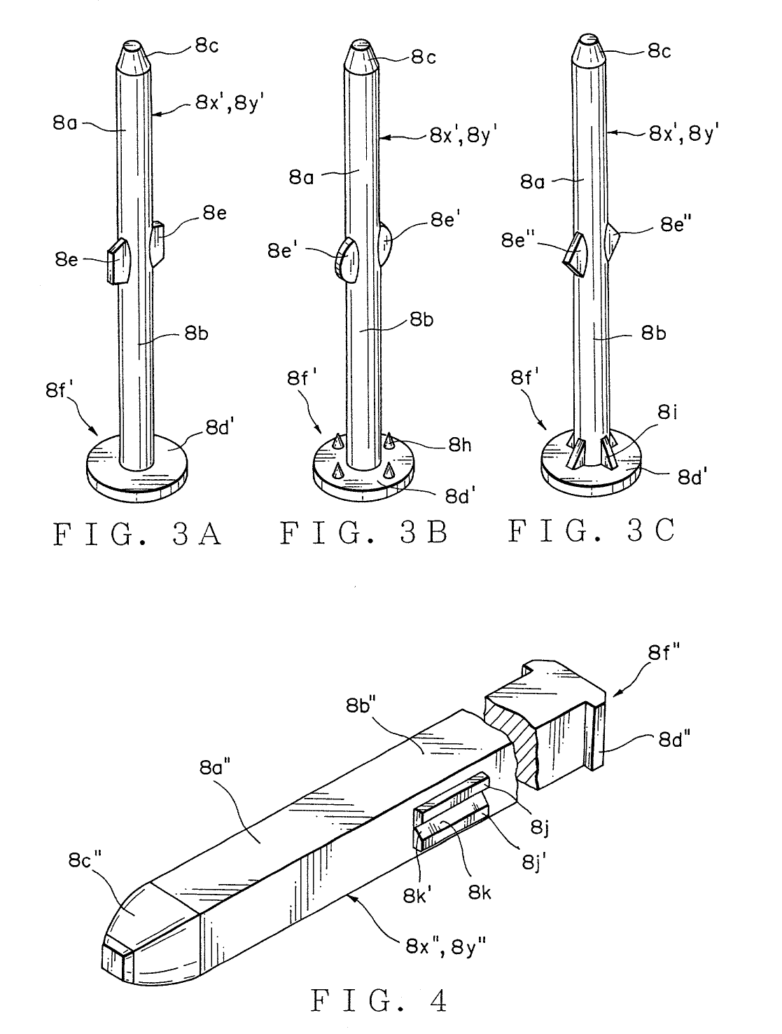

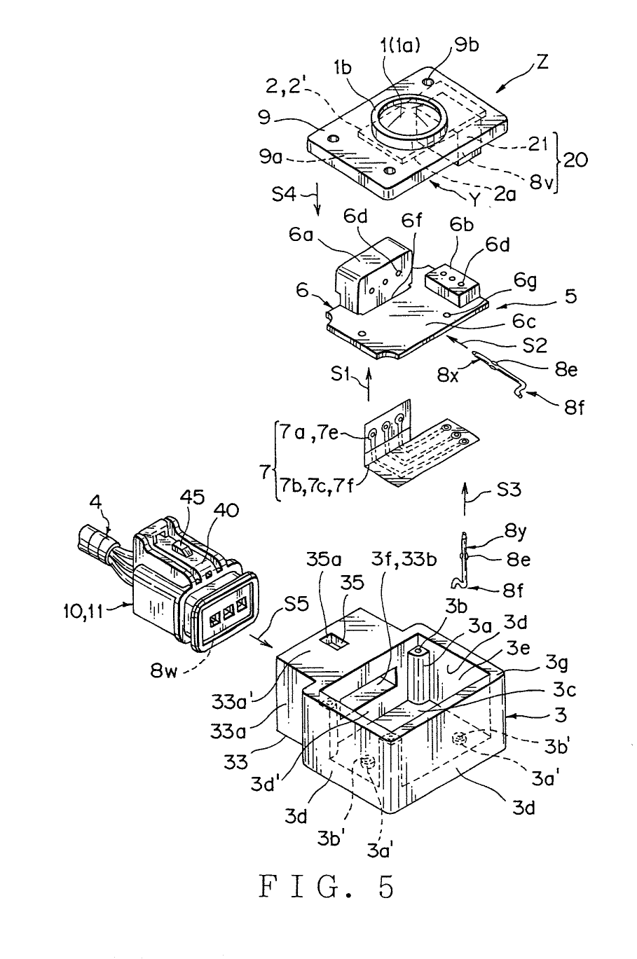

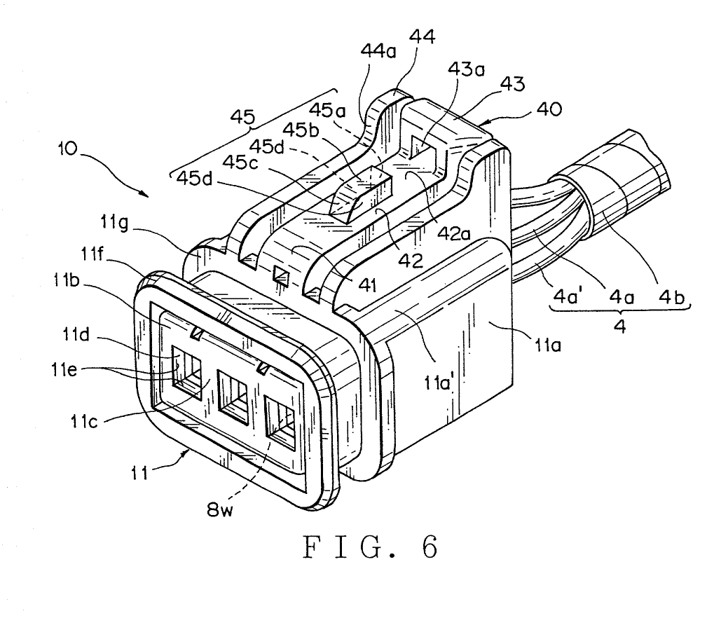

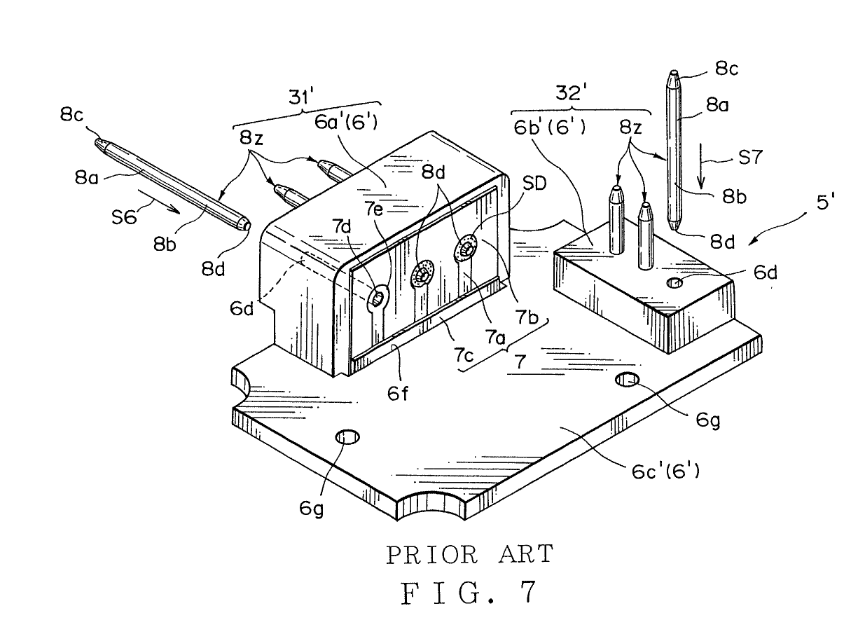

FIG. 1 is an enlarged perspective view illustrating a connection structure between a terminal and a flexible printed circuit body according to the present invention. FIG. 2 is a longitudinal cross sectional view illustrating a connection structure between a terminal and a flexible printed circuit body. Each of FIGS. 3A-3C is an enlarged perspective view illustrating an example of a terminal employed in another preferred embodiment. FIG. 4 is an enlarged perspective view illustrating an example of a terminal employed in another preferred embodiment. FIG. 5 is an exploded perspective view illustrating an auxiliary machine module according to the present invention. FIG. 6 is an enlarged perspective view illustrating a mating connector.

First, an arrangement of a connection structure between terminals 8x-8y″ and a flexible printed circuit body 7, an intermediate component 5 and an auxiliary machine module Z will be explained with reference to FIG. 5. In FIG. 5, a lens la-side of the camera module Z is defined as an upper side while a bottom wall 3c-side of a camera case 3 is defined as a lower side. A direction in which a wiring harness 4 extends from the camera case 3 is defined as the front side or this side while an inverse side thereof is defined as the rear side or the depth side. Explaining a front view and a back view, the front view is defined as viewing the connector from the fitting surface-side while the back view is defined as viewing the connector from the terminal insertion-side, that is, the wire connection-side.

In the present specification, each definition of “upper and lower”, “front and back (or rear)”, and “left and right” is for the sake of convenience, and accordingly they do not necessarily agree with the spatial directions when the connection structure between the terminals 8x-8y″ and a flexible printed circuit body 7, the intermediate component 5 and the auxiliary machine module Z are practically used. For example, in an assembly process of the auxiliary machine module Z, the intermediate component 5 or the auxiliary machine module Z may be assembled with facing any directions. The connection structure between a terminal and a flexible printed circuit body or the auxiliary machine module according to the present invention can be used in any posture thereof, provided that the purpose of the present invention is not missed.

In the following, an auxiliary machine module Y and an auxiliary machine module Z described in the present specification will be explained. The auxiliary machine module Y is defined here (i.e. in the present specification) as an assembly including at least two parts consisting of an auxiliary machine 1 such as a camera 1 and an auxiliary machine board 2 mounted on the auxiliary machine 1 and is practically called here as a camera module Y. The auxiliary machine module Z is defined here as an assembly including at least three parts consisting of an auxiliary machine 1 such as a camera 1, an auxiliary machine board 2 mounted on the auxiliary machine 1 such as a camera 1 and a case 3 such as a camera case 3 mounted on the auxiliary machine board 2, and is practically called here as a camera module Z.

A connector is here defined as a part for securing an electric connection, which includes a connector housing and a component for electric connection such as a terminal and electric wire. Such a connector may further includes a sealing member such as a seal, rubber stopper and waterproof stopper so as to improve the waterproof performance or may be attached by an additional part such as a rear holder. As a mating connector, which is fit to the connection structure between a terminal and a flexible printed circuit body of the present invention, a connector that can be welded may be used.

An electric wire (or wire) described in the present specification is defined as the general term for an electric wire including a conductor protected by an insulating coating or enamel and a conductor without coating. A cable 4a or 4a′ is also called as a core wire and consists of a conductor protected by an insulating coating or enamel, or consists of a plurality of conductors protected by an insulating coating or enamel.

An electric contact of a male terminal enters into a female terminal so as to attain an electric connection. An electric contact of a busbar having a tab enters into a female terminal so as to play a role of a male terminal for attaining an electric connection. A male terminal has a shape such as a round pin-type, square pin-type, and tab-type shape. The male terminal described in the present specification may have any shape including a shape such as various round pin-type shape as shown in FIGS. 1-3 and 5, a square pin-type shape as shown in FIG. 4, and a tab-type shape of flat plate-shape (not shown in the figures).

In the following, a male terminal 8x or 8y having a round pin-type shape as shown in FIGS. 1 and 2 will be explained together with an example of a process for manufacturing the same.

First, a long steel wire is cut to steel wires, each having a predetermined length, and thereafter each steel wire is subjected to a press working and bend working so as to form a body 8b, front end 8c, rear end 8d, a pair of projections 8e corresponding to the first locking portion 8e, an inclined portion 8g corresponding to the second locking portion 8f, and a bent portions 8g′ and 8g″. The projection 8e may be called as a dowel 8e. Each steel wire may further be subjected to a drawing working to improve the accuracy of a diameter portion of the electric contact 8a of the male terminal 8x or 8y having a round pin-type shape and other portions of the male terminal 8x or 8y.

In the process described above, for example, a long steel wire is set at an inlet of a press working machine and thereafter processed during conveying it forward. The steel wire is drawn, cut, bent and pressed per one stroke thereof and thereafter at an outlet of the press working machine the process described above is carried out by using the press working machine, which is adapted to the manufacture of the male terminal 8x or 8y having a predetermined shape, thereby the male terminal 8x or 8y is effectively rapidly manufactured.

As is seen from FIGS. 1, 2 and 5, the front end 8c of the male terminal 8x has such a shape that it becomes narrower as reaching the end thereof, that is, a taper shape so that the male terminal 8x of the connector at the camera case 3-side shown in FIG. 5 is easily inserted into a terminal receiving chamber through a terminal-receiving hole 11d of a connector housing 11 of the mating connector 10 shown in FIG. 6 when a mating connector 10 shown in FIGS. 5 and 6 is inserted into a connector constructed in the camera case 3 shown in FIG. 5 so as to carry out the fitting of the connectors with each other.

As shown in FIGS. 1 and 5, the front end 8c of the other male terminal 8y also has such a shape that it becomes narrower as reaching the end thereof, that is, a taper shape.

As shown in FIGS. 3 and 4, the front end 8c or 8c″ of an other example of each male terminal 8x′, 8y′, 8x″ and 8y″ also has such a shape that it becomes narrower as reaching the end thereof.

As a material of the terminal such as the male terminal 8x-8y″, female terminal 8v or 8w, and the busbar used in the present invention, for example, copper-based material such as bronze, brass and copper alloy, or aluminum alloy can be employed. The material of the terminal such as the male terminal 8x-8y″, female terminal 8v or 8w, and the busbar used in the present invention may be a metallic material having an electro-conductive property or a conductor having a resistance against the heat during soldering.

Further, in order to improve the corrosion resistance of the terminal, the terminal made of the material described above may be subjected to a treatment for protecting the surface thereof such as plating. However, preferably such a treatment for protecting the surface is omitted from the viewpoint of reducing the cost, provided that a sufficient performance can be maintained when used under a normal condition.

A busber is made in such a manner that the electric circuit is diverged by an electro-conductive metal plate and is constituted by an electric circuit network, in which a great number of electric contact pieces are formed. The busbar may be a busbar body, busbar for connector, busbar for relay, busbar for fuse, busbar for power source, and busbar for junction. The basbar for fuse may also be called as a nipping-type terminal or tuning fork because of its shape. A busbar for junction such as an F-F terminal may be attached to each type of busbar described above, if necessary.

The F-F terminal is a terminal having a fitting portion at both ends of the terminal and has some types such as a F-F terminal for fuse to connect a busbar to fuse and a F-F terminal for relay to connect a busbar to relay depending on a component to be connected thereto. The “F” of F-F originates from “female”.

A busbar, in which a body of the busbar is integrally formed with a tab, is preferable since the cost can be reduced. The tab formed in the vicinity of the end of the busbar functions as a terminal.

As shown in FIGS. 1 and 5, in the flexible printed circuit body (FPC) 7, a plurality of circuit conductors 7a made of metal foil such as copper foil are printed in parallel on an insulating sheet 7b and a protection layer 7c is formed thereon. Thus, the flexible printed circuit body 7 is a flexible printed wiring plate consisting of the circuit conductor 7a, insulating sheet 7b and protection layer 7c.

In the preferred embodiment, the flexible printed circuit body 7 includes the circuit conductor 7a so that three circuit conductors 7a can electro-conductively connect one side of the circuit body 7 to another side of the circuit body 7. In order to prevent the circuit conductor 7a from coming into contact with some other part, that is, to prevent an undesirable short circuit from occurring, the circuit conductor 7a is protected by the insulating sheet 7b and the protection layer 7c formed on the insulating sheet 7b.

In a molded resin part 6, a first base 6a, second base 6b and board 6c are integrally formed by injection molding. The board 6c has a rectangular flat-plate shape. The molded resin part 6 may be easily quickly injection molded by using a hot melt material of polyamide-base resin.

As shown in FIG. 5, when an intermediate connector board 5 including the molded resin part 6 is mounted on the camera case 3, in response to a shape of a though hole 3f continuing to a connector housing 33 of the camera case 3, the first base 6a as shown in FIGS. 1 and 5 is projectingly formed on the board 6c of the molded resin part 6.

As shown in FIG. 5, the camera module Y consisting of a cover 9, a CCD camera 1, an auxiliary machine board 2 and a PCB connector 20 is mounted on a camera case 3 in which the intermediate connector board 5 including the molded resin part 6. At that time, the connector 20 of the camera module Y shown in FIG. 5 is connected to a second electric connection part 32 including a second base 6b of the intermediate connector board 5 including the molded resin part 6 shown in FIG. 1. Thus, in response to the shape of the connector housing 21 of the connector 20 mounted on the auxiliary machine board 2 shown in FIG. 5, the second base 6b as shown in FIGS. 1 and 5 is projectingly formed on the board 6c of the molded resin part 6.

Three terminal insertion holes 6d for receiving the male terminal 8x, 8y and so on are formed in the first base 6a and the second base 6b. Each terminal insertion hole 6d passes through the base 6a or 6b. A pair of locking hollows 6e and a pair of guide grooves 6e′ each continuing to the corresponding locking hollow 6e are formed on the circumference of the terminal insertion hole 6d.

As shown in FIGS. 1 and 5, at the bottom of the first base 6a, an insertion hole 6f for receiving the flexible printed circuit body 7 is formed penetrating through the board 6c. As shown in FIG. 5, in order to mount and fix the intermediate connector board 5 to a receiving chamber 3e of the camera case 6, in accordance with the position of a fixing part 3a′ and an internal thread hole 3b′ formed on a bottom wall 3c of the camera case 3, two holes 6g are formed at specific positions on the board 6c as shown in FIGS. 1 and 5.

In the following, a connection structure between the male terminals 8x, 8y and the flexible printed circuit body 7 according to a preferred embodiment of the present invention will be explained in detail with reference to FIGS. 1 and 2.

As shown in FIGS. 1 and 2, the connection structure includes the bases 6a and 6b, the flexible printed circuit body 7 and the male terminals 8x and 8y.

As such a connection structure, an intermediate component 5, that is, an intermediate connector board 5 will be explained below. As shown in FIG. 1, the intermediate connector board 5 includes a molded resin part 6, a flexible printed circuit body 7, and a plurality of male terminals 8x and other male terminals 8y, each having a round pin-shape.

As shown in FIGS. 1 and 2, each of the bases 6a and 6b is provided with mounting holes 6d into which the male terminal 8x or 8y is press fit and inserted, the locking hollows 6e to which the male terminal 8x or 8y is fixed, and the guide groove 6e′ which continues to the locking hollows 6e. The flexible printed circuit body 7 is provided with a through hole 7d, into which the male terminal 8x is inserted, at the end 7e of the circuit conductor 7a. Each of the male terminals 8x and 8y includes a first locking portion 8e engaging with the locking hollow 6e of the terminal insertion hole 6d of the base 6a or 6b and a second locking portion 8f fixed to the base 6a or 6b putting the flexible printed circuit body 7 therebetween.

Then, the circuit body 7 is mounted on the base 6a or 6b and the male terminal 8x is inserted through the through hole 7d up to the terminal insertion hole 6d of the base 6a. The relation between the diameter of the body 8b of the male terminal 8x or 8y and that of the terminal insertion hole 6d may be fastening fitting, intermediate fitting or loosing fitting.

The male terminal 8x is completely fit into the terminal insertion hole 6d of the base 6a, thereby the circuit conductor 7a of the circuit body 7 comes into contact with the second locking portion 8f of the male terminal 8x. Thereby, the male terminal 8x is fixed to the terminal insertion hole 6d and is electro-conductively connected to the circuit conductor 7a of the circuit body 7. The mounting state of the male terminal 8x to the base 6a will be explained with reference to FIG. 2 in the following.

The first locking portion 8e of the terminal 8x consists of one part parallel to the length direction of the body 8b of the terminal 8x and another part of a pair of inclined parts functioning as a tapered guiding surface situated at both sides of the one part. Thus, the first locking portion 8e of the terminal 8x has a trapezoid shape. In connection therewith, there is provided a step between the locking hollow 6e formed on the circumference of the terminal insertion hole 6d and the guide groove 6e′ also formed on the circumference of the terminal insertion hole 6d.

The inclined part of the first locking portion 8e abuts against the step described above. Further, the bent portion 8g″ of the second locking portion 8f abuts against the circuit conductor 7a of the circuit body 7. Thus, the male terminal 8x is fixed to the base 6a and is electo-conductively connected to the circuit conductor 7a of the circuit body 7.

Thus, the male terminal 8x or 8y is press fit and fixed to the terminal insertion hole 6d, thereby the male terminal 8x can be electo-conductively connected to the circuit conductor 7a of the circuit body 7. Moreover, the pitch between each terminal 8x and terminal 8y can be shortened, thereby the connection structure between the terminal 8x or 8y and the flexible printed circuit body 7 can be miniaturized.

Further, since a welding process is not necessary, therefore the workability of the assembly operation can be improved. Since there is no need to use solder, therefore each part or component can be easily disassembled and the work for recycling can be easily carried out.

The first locking portion 8e is formed on the body 8b of the male terminal 8x as a pair of projections 8e having a pair of the tapered guide surfaces. The second locking portion 8f is a S-shaped bent shape, in which the body 8b is bent at the bent portion 8g′ to form the inclined part 8g and is further bent at the other bent portion 8g″ as shown in FIG. 2.

Thus, the first locking portion 8e is formed as a pair of the projections 8e provided with a pair of the tapered guide surfaces, thereby the male terminal 8x can be easily press fit to and inserted into the terminal insertion hole 6d. When the terminal 8x or the circuit body 7 should be taken off from the base 6a for the sake of recycle, the terminal 8x can be easily taken out from the hole 6d.

Since the male terminal 8x is provided with the S-shaped bent shape as described above, when the male terminal 8x is completely fixed to the base 6a, the S-shaped bent portion of the male terminal 8x abuts against the circuit body 7 or the base 6a and has a suitable restoring elastic force.

Since the terminal 8x has a pair of the projections 8e and the bent portion having the S-shape, which are separated from each other having a suitable distance therebetween, therefore when the terminal 8x is completely fixed to the base 6a, the S-shaped bent portion of the male terminal 8x has a suitable restoring elastic force and the terminal 8x is securely held by the base 6a with the aid of the S-shaped bent portion thereof and a pair of the projections 8e thereof.

As shown in FIGS. 1 and 2, the guide groove 6e′ is formed so as to continue to the corresponding pair of the locking hollows 6e formed on the circumference of the terminal insertion hole 6d. Such a guide groove 6e′ is formed on the circumference of the terminal insertion hole 6d, thereby when each terminal 8x-8y′ is inserted into and fixed to the hole 6d, each of a pair of the projections 8e-8e″ is press fit to and guided into the guide groove 6e′.

Consequently, when each terminal 8x-8y′ is inserted into the hole 6d, each terminal never rotates and accordingly is never non-uniformly mounted to the base 6a without being lined up. A pair of the projections 8e is press fit into the guide groove 6e′ in a specific direction, thereby the terminal 8x is uniformly mounted into the base 6a with being lined up as shown in FIG. 1.

With the construction described above, an undesirable short circuit is prevented from occurring because the second locking portion 8f of one terminal 8x never comes into contact with that of an adjacent terminal 8x. Thus, even if the pitch of the terminals 8x is narrow, the terminals 8x can be easily mounted into the base 6a with being lined up.

Each of FIGS. 3A-3C is an enlarged perspective view illustrating an example of the male terminal 8x′ or 8y′ having various shapes according to another preferred embodiment.

The round pin-shaped male terminal 8x′ or 8y′ having various shapes shown in FIG. 3 is the same as the male terminal 8x or 8y shown in FIGS. 1 and 2 in such points that the body 8b having a cylindrical shape functions as an electric contact 8a and a tapered guide surfaces are provided at the front end 8c, however is different from the male terminal 8x or 8y shown in FIGS. 1 and 2 in terms of a first locking portion 8e′ and a second locking portion 8f′ of the terminal 8x′ or 8y′.

The shape of the first locking portion 8e of the terminal 8x′ or 8y′ shown in FIG. 3A is the same with that of the first locking portion 8e of the terminal 8x shown in FIGS. 1 and 2. However, the second locking portion 8f′ of the terminal 8x′ or 8y′ shown in FIG. 3A is formed as a rear end 8d′ having a disc-shape with a diameter which is larger than the diameter of the cylindrical body 8b of the terminal 8x.

When the male terminal 8x′ or 8y′ shown in FIG. 3A is inserted into the terminal insertion hole 6d, the rear end 8d′ having a disc-shape abuts against the circuit conductor 7a of the flexible printed circuit body 7 and the terminal 8x′ or 8y′ is fixed to the base 6a made of synthetic resin by a pair of the projections 8e and the rear end 8d′ having a disc-shape. Thus, the male terminal 8x′ or 8y′ is securely fixed to the base 6a putting the circuit body 7 therebetween and is electro-conductively connected to the circuit conductor 7a of the circuit body 7.

The first locking portion 8e′ of a round pin-shaped terminal 8x′ or 8y′ shown in FIG. 3B is a pair of projections 8e′ having an arc-shape and formed to facilitate the taking-off of the terminal from the terminal insertion hole 6d. The shape of the second locking portion 8f′ of a round pin-shaped terminal 8x′ or 8y′ shown in FIG. 3B is formed in such a manner that four circular cone-shaped projections 8h are arranged at regular intervals on a surface of the rear end 8d′ having a disc-shape at the first locking portion 8e′-side thereof.

When the male terminal 8x′ or 8y′ shown in FIG. 3B is inserted into the terminal insertion hole 6d, a plurality of the projections 8h hit against the base 6a putting the soft flexible printed circuit body 7 therebetween, thereby the terminal 8x′ or 8y′ is securely fixed to the base 6a and is electo-conductively connected to the circuit conductor 7a of the circuit body 7.

The first locking portion 8e″ of a round pin-shaped terminal 8x′ or 8y′ shown in FIG. 3C is a pair of projections 8e″ having a triangle-shape with two inclined parts. The shape of the second locking portion 8f′ of a round pin-shaped terminal 8x′ or 8y′ shown in FIG. 3C is formed in such a manner that four inclined projection parts 8i having a triangle-shape are formed at regular intervals so that a surface of the rear end 8d′ having a disc-shape at the first locking portion 8e″-side is shortly connected to a surface of the cylindrical body 8b of the terminal 8x′ or 8y′.

When the male terminal 8x′ or 8y′ shown in FIG. 3C is inserted into the terminal insertion hole 6d, a plurality of the projections 8i hit against the vicinity of the opening of the hole 6d formed on the base 6a putting the through hole 7d at the end 7e of the soft flexible printed circuit body 7 therebetween to make a wedge effect take place, thereby the terminal 8x′ or 8y′ is securely fixed to the base 6a and is electo-conductively connected to the circuit conductor 7a of the circuit body 7.

The inclined angle of the tapered guide surface formed at each first locking portion 8e-8e″ of the corresponding terminal 8x-8y′ is set so that the tapered guide surface securely abuts against the step between the locking hollow 6e and the guide groove 6e′ when each terminal 8x-8y′ is fixed to the terminal insertion hole 6d and that each terminal 8x-8y′ never comes out from the hole 6d.

FIG. 4 is an enlarged perspective view illustrating an example of the square pin-type male terminal 8x″-8y″ employed in another preferred embodiment.

Each terminal 8x″-8y″ includes a body 8b″, front end 8c″ and rear end 8d″. A part of the body 8b″ is an electric contact 8a″. The front end 8c″ has tapered guide surfaces.

The body 8b″ is provided with a pair of first locking portions 8j, that is, projections 8j or dowel 8j. Further, a second locking portion 8f″ including the rear end 8d″ is formed.

The first locking portion 8j, that is, the projection 8j consists of a pair of trapezoid-shaped projections 8j′. A V-shaped groove 8k′ consisting of an inclined surface 8k of one projection 8j′ and another inclined surface 8k of another adjacent projection 8j′ is formed at the first locking portion 8j of the terminal 8x″ or 8y″.

The width of the second locking portion 8f′ is formed longer than that of the body 8b″. That is, the second locking portion 8f″ has a T-shape.

With the construction of the first and second locking portions, 8j and 8f′, respectively, the male terminal 8x″ or 8y″ is securely fixed to the corresponding mount of the mating component.

Each terminal 8x-8y″ has the first locking portion 8e-8e″ or 8j and the second locking portion 8f-8f′ and the distance therebetween is set suitable, thereby each terminal 8x-8y″ is securely mounted in the base 6a.

Since the shape of the second locking portion 8f-8f″ is a S-shape as shown in FIGS. 1 and 2, disc-shape as shown in FIG. 3 or T-shape as shown in FIG. 4, each male terminal 8x or 8y can be easily nipped by the fingers, and during assembly or disassembly for the sake of recycle the male terminal 8x or 8y can be excellent in terms of the workability of assembly and disassembly.

FIG. 5 is an exploded perspective view of the intermediate connector board 5 and the auxiliary machine module Z according to the preferred embodiment of the present invention. In the following, a camera module Z into which the intermediate connector board 5 is assembled will be explained together with each parts or components, an assembly sequence and assembly method.

First, a CCD which is assembled into a CCD camera 1 and carries out an important function will be explained. The CCD mainly means a charge coupled device, and more specifically means a device, which converts a signal picked up as a light such as an image to an electric signal by using a semiconductor element that is reactive against the light. The CCD is a semiconductor, which is disclosed by the Bell Telephone Laboratory in United States of America in 1970. In general, the quality of images of the CCD depends upon the number of pixels, which is widely set from several hundreds of thousands to several millions. The number of pixels may increase in the future as the need arises.

The CCD has been widely employed in a camera such as a digital camera and video camera, facsimile, scanner, and copy machine such as copier or laser beam printer. In case of digital camera, a CCD is disposed at the focusing part instead of a silver film. Recently, a CCD having large number of pixels becomes cheap contributing to cost down of a digital camera and increasing in picture quality.

A camera 1 used as an auxiliary machine 1 can be any type of camera such as a camera employing a CCD and a camera employing metal oxide semiconductors (MOS). In the following, relating to a camera 1 used as an example of the auxiliary machine module Z according to the present invention, a solid state image pickup element of a CCD mounted to the camera 1 will be explained in detail.

A CCD mainly includes a photodiode, i.e. photosensitive element, transfer gate, and overflow drain. There are some types of transfer, frame transfer, interline transfer and so on, for a CCD depending upon a way to pick up a charge. In general, a longitudinal transfer section is provided at the side of a photosensitive section and a transfer gate is disposed therebetween. Such a CCD employs a board having high resistivity and a p-well provided under a n-layer of the longitudinal transfer section so that an optical charge generated in the depth of the board is prevented from flowing into a transfer section, thereby a smear phenomenon is prevented from occurring.

In a solid state image pickup element of a CCD, photosensitive sections, overflow drains, and longitudinal/horizontal transfer sections are densely arranged on a silicon substrate of less than 10 mm×10 mm square. On such a silicon substrate, about 200 thousands to 6 million of pixels are systematically arranged. For example, when 1500 pixels×2000 pixels are arranged lengthwise and crosswise, respectively, totally 3 millions of pixels are arranged on a silicon substrate.

When an optical image of a subject is formed on such a silicone substrate through a lens, photoelectrons, the number of which corresponds to the brightness of each pixel, are generated in each pixel. That is, the object is converted to an image of electrons. Thereafter, a number of pixels arranged on a surface are resolved by a horizontal scanning line and the photoelectrons are taken out as a projected image signal.

A photocharge generated with an incident light all together moves into a longitudinal transfer CCD when a transfer pulse is added. Thereafter, when a transfer pulse is added to the longitudinal transfer CCD, the photocharge is transferred from one pixel to another in turn in the CCD and reaches the horizontal transfer CCD, then is transferred horizontally successively every horizontal scanning period of time and is taken out as a signal from an output section.

In order to make a CCD dense, a solid state image pickup element having a two-layer structure, in which a highly photosensitive element such as a target film of an image pickup tube is piled on the charge transfer section, is employed. In the future, as for a solid state image pickup element, high sensitivity like an image pickup tube, improvement of resolution and reduction of moire, and contraction of image size will be further tried, thereby a CCD with high performance and low cost is expected to appear.

A MOS means a metal oxide film semiconductor and is employed in an integrated circuit having an advantage of consuming less electric power. In a MOS-type solid state image pickup element, photocharges, the number of which responds to the intensity of an incident light, are generated. Such a MOS-type element includes a number of pixels arranged systematically, each of which includes a photodiode for tentatively storing photocharges and a transistor functioning as a switch for taking out the photocharges stored in the photodiode.

In the following, each part constituting a camera module Y or Z will be explained in turn in detail. As shown in FIG. 5, a camera 1 includes a lens 1a, surrounds 1b of the lens 1a, and a CCD inside, thereby constituting a CCD camera 1.

As shown in FIG. 5, as for an auxiliary machine board 2, a board body 2′ has a rectangular parallelepiped-shape. The board body 2′ made of synthetic resin is provided with a plurality of circuit conductors (not shown in the figure), each made of a metal foil such as a copper foil, thereby a printed wiring plate is formed. An insulating coating is formed on the printed wiring plate including circuit conductors so as to prevent an electrical leak or short circuit from occurring, thus the auxiliary machine board 2 is formed. Such an auxiliary machine board is also called as a printed board (printed wiring board).

Various electric circuits (not shown) for connecting to each electric wiring such as a relay, fuse, capacitor, semiconductor, terminal, busbar, connector and electric wire are held on the board body 2′ as the need arises. The auxiliary machine board 2 holds these various electric circuits thereon and is an electrically insulating board for preventing an undesirable electrical contact among the various electric circuits from occurring. Consequently, the auxiliary machine board 2 may be called as an insulating board.

As is seen from FIG. 5, a connector 20 consisting of female terminals 8v and a connector housing 21 is fixed to a lower surface 2a-side of the auxiliary machine board 2. An end of the female terminal 8v received in a chamber of the connector housing 21 of the connector 20 is electrically connected to a circuit conductor made of a metal foil such as a copper foil provided on the auxiliary machine board 2 by soldering. To such a PCB connector 20, a second connector body 32 of the intermediate component 5 shown in FIG. 1 is connected.

As shown in FIG. 5, the camera land the auxiliary machine board 2 including the connector 20 are mounted on the lower surface 9a of the cover 9, thereby the camera module Y is constructed. Three holes 9b for fixing the cover 9 to the camera case 3 are provided at three positions in the vicinity of corners of the cover 9, on which the camera 1 and the auxiliary machine board 2 including the PCB connector 20 are mounted. Stops such as three screws (not shown) are inserted and screwed into the hole 9, thereby the camera module Y and the camera case 3 is assembled with each other.

As a resin material for the auxiliary machine board or the molded resin part 6 which constitutes the intermediate component 5 for the auxiliary machine module, i.e. the intermediate connector board 5, for example, a synthetic resin such as a heat-hardening resin and thermoplastic resin is preferable because it has good moldability and can excellently insulate various electric parts such as terminals or busbars. For example, if the resin material is such a synthetic resin having water absorption property, it is excellent in terms of dimensional stability, mass-productivity, and stable electric performance.

Further in terms of rapid moldability, for example, a thermoplastic synthetic resin can be used for the molded resin part 6 which constitutes the intermediate connector board 5, and especially hot melt material is preferably selected as the thermoplastic synthetic resin. A hot melt material is a kind of a special adhesive which is softened or melted by heating and then cooled so as to be hardened rapidly.

Since the hot melt material has such a property, when the hot melt material is used for a molding work, a rapid molding process can be attained so as to improve the productivity. The hot melt material is an adhesive consisting of a thermoplastic resin base and is one of the types of so-called resin solder.

An example of the hot melt material is a material containing ethylene-vinyl acetate copolymer (EVA) as a base polymer, material containing ethylene-ethyl acrylate copolymer (EEA) as a base polymer, and material containing a base polymer such as polyamide (PA), polyuretane (PUR), polyethylene (PE), polyester, and atactic polypropylene.

A reactive hot melt such as PUR-based material having improved heat resistance or an adhesive hot melt instead of solvent-type adhesive has been put to practical use. An aqueous hot melt has been investigated in terms of the environmental or economical consideration. The hot melt material of polyamide base is preferable in terms of moldablility and cost.

The female terminal 8v of the PCB connector 20 is soldered to a specific position of the circuit conductor provided on the board body 2′ so as to be integrated. Thus, the PCB connector 20 is constructed as a portion of the auxiliary machine board 2.

A connector, which is soldered to the circuit conductor provided on the printed wiring board such as the auxiliary machine board 2 and flexible printed circuit body, is called as a PCB (printed circuit board) connector. A terminal used in the PCB connector is generally a square pin-type busbar. However, a terminal in a connector, which is used in the present invention, may be any type of terminal.

The PCB connector is mainly classified into two types of mounting, i.e. longitudinal mounting and horizontal mounting. As for the longitudinal mounting-type PCB connector, the coupling direction between male and female terminals is longitudinal relatively to the board. To the contrary, as for the horizontal mounting-type PCB connector, the coupling direction between male and female terminals is horizontal relatively to the board.

As shown in FIG. 5, in the camera case 3, a chamber 3e is formed being surrounded by a bottom wall 3c and four side walls 3d. In the chamber 3e, three pairs of fixing part 3a and internal thread hole 3b are provided associating with three holes 9b, which are provided in the vicinity of the corresponding three corners out of four corners of the cover 9.

In order to mount and fix the intermediate connector board 5 including the molded resin part 6 in the chamber 3e of the camera case 3, as shown in FIG. 5, two pairs of fixing part 3a′ and internal thread hole 3b′ are provided on the bottom wall 3c of the camera case 3 associating with two holes 6g provided at specific positions on the board 6c.

In order to protect and shield the various electric parts arranged on the back side of the camera module Y from the outside when the camera module Y is mounted in the camera case 3, a mating surface 3g consisting of an uniform plane is formed at the upper end surface-side of each side wall 3d of the camera case to face another mating surface consisting of an uniform plane formed in the vicinity of four corners of the cover 9 at the back surface 9a-side. As shown in FIG. 5, a through hole 3f is formed from the chamber 3e toward the outside of the camera case 3. The through hole 3f continues to the opening of the connector housing 33.

As shown in FIG. 5, the connector housing 33 is formed being surrounded by four side walls 33a and 33a′ and has a box-shape when viewed from the electric wire-side. A chamber 33b for receiving mating connectors is formed in the connector housing 33.

When the mating part, i.e. mating connector 10 is fit to the connector constructed in the camera module Z, a slidable contact surface 45b of a locking projection 45 provided on a locking arm 40 of the mating connector 10 comes in slidable contact with an mating slidable contact surface inside a top wall 33a′ of the connector housing 33.

As shown in FIG. 5, a locking part 35, i.e. locking hole 35 for engaging with the locking projection 45 of the locking arm 40 is provided on the top wall 33a′.

The locking hole 35 is constructed by a locking surface 35a formed at the opening side of the connector housing 33, a side surface facing the locking surface 35a and two side surfaces perpendicular to the locking surface 35a. Thus, the locking hole 35 has a rectangular through hole-shape to engage with the locking projection 45 of the mating connector 10.

The locking surface 35a of the locking hole 35 is formed crossing at right angle with the inner surface of the top wall 33a′ including the slidable contact surface described above formed in the connector housing 33. As is seen from FIGS. 5 and 6, the locking surface 35a mates with a locking surface 45a of the locking projection 45.

The connector housing 33 is made of the same material as that of the case 3 such as the camera case 3 and formed integrally therewith by injection molding, thereby preventing the number of the parts from increasing, preventing the manufacturing process from becoming complicated, and preventing the cost of the auxiliary machine module Z such as the camera module Z from raising up.

Preferably, the camera case 3 or the cover 9 for protecting the camera 1 is made of aluminum alloy such as aluminum die casting in terms of light weight, mechanical strength, corrosion resistance, workability and productivity.

Preferably, the CCD camera 1 mounted on the exterior of a motor vehicle has corrosion resistance since it is exposed to the weather and is made of material having low density in terms of the light weight of the motor vehicle.

As shown in FIG. 5, the camera module Y, including the CCD camera 1 and the auxiliary machine board 2 having the PCB connector 20 consisting of the female terminal 8v and the connector housing 21, is prepared to be mountable in the camera case 3.

The molded resin part 6, flexible printed circuit body 7, a plurality of the round pin-type male terminals 8X and other male terminals 8y are assembled with each other, thereby the intermediate connector board 5 shown in FIG. 1 is constructed.

In the following, a sequence for assembling the intermediate connector board 5 will be explained in detail. As shown in FIG. 5, the circuit body 7 is mounted to the molded resin part 6 along a direction of arrow SI. That is, one end of the circuit body 7 is inserted into the insertion hole 6f, which is formed penetrating through the board 6c, from the bottom of the first base 6a. The circuit body 7 shown in FIG. 1 is fixed on a specific position of the molded resin part 6 by means of various adhesive means such as an adhesive and adhesive tape or mounting means such as the male terminals 8x and 8y.

As is seen from FIG. 5, the circuit body 7 is formed in a L-shape and accordingly the three circuit conductors 7a are extended in two different directions, in which one direction crosses at about 90° with another direction, thereby the length direction of the one male terminal 8x can be set to be a direction intersecting at about 90° with the length direction of the another male terminal 8y.

As is seen from FIGS. 1 and 5, the male terminal 8x, which includes the first locking portion 8e consisting of a pair of the projections 8e and the second locking portion 8f having a S-shape, is inserted into the through hole 7d formed at the end 7e of the circuit conductor 7a of the circuit body 7 starting from its end 8c along a direction of arrow S2. Then, the terminal 8x is press fit to, inserted into and mounted to the terminal insertion hole 6d, guide groove 6e′ and locking hollow 6e, thereby a first electric joint 31, that is, a first connector body 31 is formed.

As is seen from FIGS. 1 and 5, the other male terminal 8y, which includes the first locking portion 8e consisting of a pair of the projections 8e and the second locking portion 8f having a S-shape, is inserted into the through hole formed at the other end of the circuit conductor 7a of the circuit body 7 starting from its end 8c along a direction of arrow S3 (see FIG. 5). Then, the other terminal 8y is press fit to, inserted into and mounted to a terminal insertion hole 6d, guide groove and locking hollow 6e, thereby a second electric joint 32, that is, a second connector body 32 is formed. As is seen from FIGS. 1 and 2, a pair of the projections 8e of the male terminal 8x or 8y is completely inserted into the step between a pair of the locking hollows 6e, which is formed around the hole 6d of the base 6a or 6b, and the guide groove 6e′, thereby the circuit conductor 7a elastically comes into contact with the bent portion 8g″, which forms a portion of the second locking portion 8f of the male terminal 8x or 8y. Thus, the intermediate connector board 5 shown in FIG. 1 is assembled and the male terminal 8x of the first connector body 31 is electro-conductively connected to the other male terminal 8y of the second connector body 32 by the circuit conductor 7a of the flexible printed circuit body 7.

Then, the camera module Y shown in FIG. 5 and the intermediate connector board 5 shown in FIG. 1 are assembled into the chamber 3e of the camera case 3 shown in FIG. 5, thereby the camera module Z is assembled.

The through hole 3f and connector housing 33 are formed in the camera case 3 to receive the first connector body 31, which is formed on the intermediate connector board 5. The intermediate connector board 5 is moved along a direction of arrow S4 (see FIG. 5) and mounted into the chamber 3e of the camera case 3.

At that time, the first connector body 31 is mounted into the connector housing 33, thereby a connector is constructed in the camera case 3. Thereafter, a stop such as a screw (not shown in the figure) is engaged with the internal thread hole 3b′ of the fixing part 3a′ provided on the bottom wall 3c of the camera case 3 through the hole 6g for mounting the intermediate connector board 5. The screw is tightened by using a spanner or screwdriver, thereby the intermediate connector board 5 is securely fixed in the chamber 3e of the camera case 3.

Thereafter, as shown in FIG. 5, the camera module Y is moved along the direction of arrow S4 and mounted into the camera case 3, thereby the PCB connector 20 provided on the auxiliary machine board 2 is mated with the second connector body 32 constructed on the intermediate connector board 5. Thereby, the female terminal 8v of the PCB connector 20 is electro-conductively connected to the other male terminal 8y of the second connector body 32.

Thereafter, a stop such as a screw (not shown in the figure) is engaged with the internal thread hole 3b of the fixing part 3a provided at three positions out of four corners of the chamber 3e through the hole 9b of the cover 9. The screw is tightened by using a spanner or screwdriver, thereby the camera module Y is securely fixed in the camera case 3.

With the assembly described above, the CCD camera 1 can be isolated from wires such as the wiring harness 4, therefore various parts to be mounted to the CCD camera 1 can be assembled in a step which is different from a step for assembling the wiring harness 4, thereby assembly operation can be improved. Since the intermediate connector board 5 including the male terminals 8x and 8y is used to assemble the camera module Z, therefore a connector is easily constructed in the camera module Z upon the assembly operation. Further, since the number of parts used in the electric joint can be reduced, therefore the cost down of the camera module Z can be attained and the assembly operation of the camera module Z may be automated.

With the construction of the camera module Z described above, the intermediate connector board 5 is assembled into the connector housing 33, thereby a connector is constructed in the camera module Z, and the auxiliary machine board 2 including the CCD camera 1 is received in the chamber 3e of the camera case 3, thereby the CCD camera 1 is connected to the intermediate connector board 5. Accordingly, the camera module Z, which is excellent in terms of its assembly operation, can be provided and the module Z is not required to be disassembled when the wiring harness 4 should be taken off from the module Z.

Thus, the camera module Z can be easily assembled and accordingly easily disassembled as well, thereby the structure of the module Z is adapted to carry out the recycle.

Further, a product having poor quality is prevented from being produced. As for a camera module having a conventional structure, when an auxiliary machine board 2, on which a CCD camera and the like is mounted, is mounted into a case 3, there has been a possibility that a wire is caught between the auxiliary machine board 2 and the case 3, resulting in that such an auxiliary machine module should be treated as a defective product since the wire may be cut in the module.

To the contrary, the auxiliary machine module such as the camera module Z according to the present invention prevents such a defective product from being produced.

With the construction of the auxiliary machine module Z according to the present invention, the module Z can be quickly assembled and a complicated assembly operation, which has been needed in the assembly operation of a conventional auxiliary machine module, is not needed. Further, since a normalized general connector can be used as the mating connector 10, which is connected to the auxiliary machine module Z, therefore the reduction of man-hour for management and of the cost can be attained.

As shown in FIGS. 5 and 6, the wiring harness 4 is mounted with extending toward this side in the figure from an opening at the wire-side of a connector housing 11 of the mating connector 10, thus the wiring harness 4 is connected to the mating component, i.e. the mating connector 10. Cables 4a, 4a′ and so on, each of which is electrically connected to its mate, are bound to one by using a bundling tape 4b or a flexible waterproof tube, thereby the wiring harness 4 is constructed.

In the following, the wiring harness will be explained in detail. A wiring harness is defined as a group of electric wires, in which according to a kind, model and grade of a motor vehicle on which the wiring harness is mounted, electric wires and so on are collected in advance at a wire maker in order that an assembly of wires and so on are easily carried out in an assembly line of a motor vehicle. Most of electric wires for use in a motor vehicle are manufactured as a harness.

An electric wire of the cable 4a or 4a′ of the wiring harness 4 mainly consists of a conductor and an insulating coating, thereby forming a core wire. The wiring harness 4 constituted by binding the cables 4a, 4a′ and so on together is bent at a specific portion thereof when mounted on a motor vehicle.

The material for the conductor of the electric wire is preferably, for example, copper-based material such as annealed copper in terms of high electro-conductive property and flexibility. In cable 4a or 4a′, a plurality of conductors are bound together and twisted moderately. In order to improve the insulating property of the surface of the conductor, a conductor coated with enamel may be used for an electric wire of the cable 4a or 4a′, or the wiring harness4.

Preferably, the insulating coating or the tube for protecting the conductor is made of a flexible insulating material such as a thermoplastic material such as vinyl chloride-based polymer and polyethylene-based polymer, rubber material, and mixture thereof. Various filler may be added to the insulating material. When such an insulating coating material is, for example, injection molded, the conductor such as copper wire is inserted into an injection hole of a die, thereby the insulating coating is combined with the conductor and accordingly the cable 4a or 4a′, or the wiring harness 4 is constructed.

The wiring harness 4 is bent at a specific portion thereof according to the shape of a motor vehicle and mounted on a specific position of the motor vehicle, thereby an electric connection between each parts or devices is carried out. A dummy wire may be also provided to the wiring harness 4 besides the cable 4a or a drain wire 4a′ in order to make electric connection with other electric circuits as the need arises.

An electric part is electro-conductively connected to the camera module Z through a non-waterproof connector provided in the vehicle by using the wiring harness 4. A drain wire 4a′ branches from an intermediate portion of the wiring harness 4, a terminal is attached to an end of the drain wire 4a′, and the terminal is attached to a frame of the vehicle body by a screw and the like. Thus, the drain wire 4a′ is attached to the vehicle body, thereby the drain wire 4a′ is electro-conductively connected to the vehicle body so that the drain wire 4a′ functions as a ground.

There are some types of the wiring harness 4 such as a circuit body consisting of flat wire, circuit body consisting of a ribbon wire having a round conductor, flexible printed circuit body (FPC), and flexible flat circuit body (FFC).

In the flexible flat circuit body (FFC), a plurality of circuit conductors consisting of thin strip, thin single wire or enameled wire are arranged in parallel on an insulating sheet. Thus, the wiring harness used in the present invention may be any type of wiring harness including a wiring harness constructed by binding a plurality of cables or core wires together and a wiring harness, in which a plurality of circuit conductors are arranged in parallel.

Besides a wiring harness in which a plurality of cables 4a, 4a′ and so on shown in FIGS. 5 and 6 are bound, any type of wiring harness can be used for the present invention, including a wiring harness in which electric wires and optical fibers are mixed and a wiring harness in which optical fibers are bound. Another additional part such as a grommet may be attached to the wiring harness.

In the following, a mating part, i.e. mating connector 10 which fits to the connector constructed in the camera module Z will be explained with reference to FIGS. 5 and 6. The mating connector 10 mainly includes a connector housing 11 formed by a side wall 11a, top wall 11a′ and front wall 11b, a chamber thereof, and female terminals 8w received in the chamber.

In order to facilitate that the mating connector 10 shown in FIG. 6 is inserted into the chamber 33b at the camera case 3-side shown in FIG. 5 when mating connector 10 fits to the connector constructed in the camera case 3, as shown in FIG. 6, a tapered guide surface 11f is formed in the vicinity of an end periphery of the front wall 11b of the connector housing 11.

In order that the three female terminals 8w are bound with and electrically connected to the corresponding three male terminals 8x in the connector constructed in the camera module Z, the front wall lib of the connector housing 11 is provided with three terminal insertion holes lid and partition walls 11c.

In order to facilitate that the male terminals 8x are inserted into the chamber of the connector housing 11 of the mating connector 10 when mating connector 10 fits to the connector constructed in the camera case 3, as shown in FIG. 6, a tapered guide surface 11e is formed in an opening of the terminal insertion hole lid of the connector housing 11.

As shown in FIG. 6, a groove 11g is provided between the front wall 11b and a base part 41 of a locking arm 40. A ring-shaped O-ring made of rubber may be fit into the groove 11g. An opening at the wire-side for receiving the wires such as the cables 4a, 4a′ and so on or a wiring harness 4 is formed at an opposite side of the terminal insertion holes lid. The opening at the wire-side may be provided with a waterproof stopper made of rubber having a sealing hole for receiving various wires according to the internal shape of the connector housing 11 of the mating connector 10.

Further, a ring-shaped waterproof O-ring made of rubber may be fit into the depth-side of the chamber 33b for receiving the mating connector 10 according to the internal shape of the connector housing 33.

Thus, the mating connector 10 and the connector of the camera case 3-side may be set as a waterproof connector, so that the penetration of water or dust into the interior of the camera case 3 or the camera 1 is prevented from occurring, thereby protecting the various electric parts or components. A general normalized mating connector or non-waterproof mating connector may be used as well.

The cable 4a, drain wire 4a′ and so on are extended into the connector housing 11 of the mating connector 10 from a portion at which the winding of a tape 4b of the wiring harness 4 is completed.

In the connector housing 11, a part of the insulating coating at the end of the cable 4a and drain wire 4a′ is peeled off and a part of the conductor is exposed to air. Such a conductor and insulating coating of the cable 4a and drain wire 4a′ are caulked with a specific wire connection part of a female terminal, i.e. a conductor crimp piece and coating crimp piece, by using a special-purpose jig, thereby the wire connection part of the female terminal 8w is fixed and connected to the cable 4a and drain wire 4a′. The wiring harness 4 may be bound by a waterproof tube. Any type of a wiring harness 4 may be used.

The female terminal 8w connected to the cables 4a, 4a′ and so on of the wiring harness 4 is inserted into a specific terminal insertion chamber in the mating connector 10 and securely fixed thereto by a locking lance and the like provided in the chamber. The locking lance may be replaced by any member having various shapes, including an arm-shaped member, for example.

Regarding a terminal being connected to the electric wires of the cable 4a or 4a′, a crimp terminal (solderless terminal) will be explained in the following. A crimp terminal has a barrel being plastically deformed by using a crimping tool upon mechanical and electrical connection with an electric wire. In general, the crimp terminal has a wire barrel, i.e. conductor crimp piece for crimping a conductor portion of the wire and an insulation barrel, i.e. coating crimp piece for crimping an insulating coating of the wire. The wire barrel has two types, i.e. a close barrel and an open barrel.

A female terminal mates with a male terminal by receiving the male terminal therein so that an electric connection is carried out. Some female terminal includes an elastic contact piece such as a spring for generating a contact load. The female terminal 8v or 8w used in the preferred embodiment of the present invention is cylindrical one having a box-shape to mate with a round pin-type male terminal 8x or 8y and has an elastic contact piece inside. Besides such a cylindrical one having a box-shape, any type of female terminal may be used including, for example, a square cylindrical female terminal to mate with a square pin-type or flat plate-shape tab-type male terminal.

As shown in FIG. 5, the mating connector 10 including the connector housing 11 which receives the female terminals 8w connected to the wiring harness 4 therein mates with the connector constructed in the camera case 3 having the male terminals therein, thereby an electrical connection between the female and male terminals is attained.

Thus, the mating connector 10 to which the wiring harness 4 is mounted is only mated with the connector formed at the camera case 3-side so that the electric connection is attained, therefore there is no need to employ a connector or its mating connector having a complicated and special structure. Accordingly, a low cost camera module Z can be provided without increasing the number of parts.

Further, a fitting or removal between both connectors (i.e., the connector constructed in the camera module Z and the mating connector 10) can be easily quickly carried out.

A normalized general connector can be used as the mating connector 10, thereby the reduction of man-hour for management and of the cost can be attained.

As shown in FIGS. 5 and 6, a locking arm 40 made of resin that is the same resin material for the mating connector is formed integrally with the top wall 11a′ on the top wall 11a′ of the connector housing 11 made of resin. Such a locking arm 40 will be explained in the following. The locking arm 40 mainly includes the base part 41, an arm 42 and operation part 43. A reference surface 42a of the arm 42 is formed being about parallel with an outer surface of the top wall 11a′ on which the locking arm 40 is provided.

A pair of projecting parts 44 is formed on the top wall 11a′ of the connector housing 11 being about parallel with the side wall 11a and putting the locking arm 40 therebetween.

The pair of the projecting parts 44 prevents the electric connection from being cut in the event that the engagement between both connectors is released when the mating connector is hit by something and the operation part 43 is strongly pushed. Thus, the pair of the projecting parts protects the locking arm 40.

The arm 42 is extended toward the operation part 43 from the base part 41. For example, the back surface of the reference surface 42a of the arm 42 may be formed gradually parting away from the top wall 11a′ from the front to the rear of the arm 42.

The shape of the arm 42 may be an inverse hollow-shape from the base part 41 to the operation part 43 to reduce the cost and simultaneously maintain the mechanical strength of the arm 42.

The locking projection 45 for engaging with the locking hole 35 of the connector of the camera module Z is formed on the reference surface 42a situated at about the center of arm 42 of the mating connector 10. The locking projection consists of a locking surface 45a, slidable contact surface 45b, inclined toughing surface 45c and two side surfaces 45d.

The locking surface 45a is formed about perpendicular to the reference surface 42a and faces the locking surface 35a formed at the opening side of the connector housing 33.

The operation part 43 protrudes from the reference surface 42a, so that the release of the locking arm 40 can be easily carried out by fingers or a jig.

The operation part 43 has a half H-shape having a run off part 43a for taking off a mold upon injection molding. The run off part 43a has an inverse hollow-shape.

With the construction described above, both connectors can be easily quickly mated or released each other, providing the camera module Z, by which the electric connection can be easily and quickly carried out.

When both connectors is coupled with each other, the electric connection between the mating connector and the camera module Z is attained. The mating connector 10 is easily quickly coupled with or released from the connector of the camera module Z. Further, the coupling between both connectors described above is not abruptly released once the coupling is completed.

When the mating connector 10 starts being inserted into the connector housing 33, the locking arm 40 starts being inserted into the connector housing 33 from the base part 41 thereof.

When the insertion proceeds further, the inclined slidable contact surface 45c of the locking projection 45 abuts against the top wall 33a′ of the connector housing 33, that is, abuts against a corner where the inner surface of the top wall 33a′ including a slidable contact surface provided in the connector housing 33 intersecting a rear end surface of the connector housing 33.

When the mating connector 10 is further inserted into the chamber 33b for receiving the mating connector 10, the slidable contact surface 45b of the locking projection 45 comes in slidable contact with the slidable contact surface of the inner surface of the top wall 33a′. In such a state, the mating connector 10 enters into the chamber 33b.

At that time, the locking arm 40 made of resin is elastically deformed. That is, the locking arm 40 is elastically deformed toward the top wall 11a′-side having a restoring force within a range of the vicinity of the base part 41 or the whole length of the arm 42.

Thereafter, the locking projection 45 climbs over the slidable contact surface of the inner surface of the top wall 33a′ and enters into the locking hole 35 provided in the connector housing 33.

Simultaneously, the once deformed locking arm 40 made of resin recovers its original state, thus the locking projection 45 and the locking hole 35 are engaged with each other.

That is, the once deformed locking arm 40 recovers about its original posture by the storing force stored inside the locking arm 40, thus the locking surface 45a of the locking projection 45 abuts against or faces the locking surface 35a of the locking hole 35, thereby the locking projection 45 and the locking hole 35 are securely engaged with each other.

At that time, the reference surface 42a of the arm 42 abuts against or faces the inner surface of the top wall 33a′ including the slidable contact surface.

The connector in the camera module Z is coupled with the mating connector in such a state, therefore the electric connection between the camera module Z and the wiring harness 4 is prevented from being cut even in the event that the wiring harness 4 is abruptly pulled toward this side in the figure so that the mating connector 10 is pulled out from the connector in the camera module Z.

When both connectors are coupled with each other, a front surface 44a of a pinched part of the pair of the projecting parts 44, which is formed in connection with the operation part 43, faces the rear end surface formed on the connector housing 33 putting a small gap therebetween so as to be able to abut against each other.

Thus, the front surface 44a of the pinched part of the pair of the projecting parts 44 is formed in connection with the operation part 43 and in such a condition the mating connector 10 is being coupled with the connector in the camera module Z, thereby the coupling or releasing of both connectors can be easily carried out and the coupling state of both connectors can be securely stably maintained.

For example, there is a possibility that the mating connector 10 might excessively be pushed into the connector in the camera module Z when the mating connector is being coupled with the connector in the camera module Z or when the mating connector is accidentally hit against another thing.

However, if the front surface 44a of the pinched part of the pair of the projecting parts 44, which is formed in connection with the operation part 43, faces the rear end surface formed on the connector housing 33 so as to be able to abut against each other, the mating connector is not pushed excessively into the depth of the connector of the camera module Z.

Accordingly, each surrounding part including the connector of the camera module Z or each part in the camera case 3 is prevented from being damaged. Further, the position of each part is prevented from being undesirably shifted. Further, the mating connector 10 is prevented from being damaged.

With the function of the locking projection 45 and the locking hole 35 as described above, the coupling of both connectors can be securely stably carried out. Further, upon the operation of the coupling, it can be easily recognized by a worker that such a secure coupling is completed. Furthermore, upon the operation of the separation of both connectors, the separation can be securely carried out.

When the mating connector 10 attached to the wiring harness 4 is separated from the camera module Z, the locking arm 40 of the mating connector is released and the mating connector 10 is pulled out from the connector in the camera module Z. That is, the operation part 43 is sufficiently pressed toward the top wall 11a′ by a finger or the like, thereby the locking arm 40 is bent toward the top wall 11a′.

Thereby, the locking surface 45a of the locking projection 45 comes off from the locking surface 35a of the locking hole 35. On such a condition, the mating connector 10 is pulled out from the connector at the camera case 3-side (i.e. the connector in the camera module Z), thereby the wiring harness 4 can be easily quickly separated from the camera module Z.

The positional relationship between the locking projection 45 and the locking hole 35 in relation to the pair of the mating connector 10 and the connector in the camera module Z can be reversed. That is, in contrast with the preferred embodiment described above, the locking projection 45 may be formed at the connector in the camera module Z and the locking hole 35 may be formed at the mating connector 10. Similarly, the positional relationship between the male and female terminals may be reversed and the positional relationship between the male and female connectors may be reversed.

Preferably, each part such as the camera case 3, molded resin part 6 of the intermediate connector board 5, and the connector housing 11 of the mating connector is formed by injection molding by using synthetic resin for material of such a part. The synthetic resin is preferably a thermoplastic resin. Each part may be formed by another molding method instead of injection molding depending upon the shape of such a part.

The connector housing 11, in which the locking arm 40 and the locking lance are integrally molded, is preferably made of the synthetic resin because such a molded member made of the synthetic resin can store a suitable restoring elastic force therein.

That is, when the locking hole 35 engages with the locking projection 45 so as to securely make both connectors be coupled with each other, the locking arm 40 made of the synthetic resin can be easily elastically deformed within a range of the vicinity of the base part 41 or the whole length of the arm 42.

After the locking arm 40 is moderately deformed elastically, the locking projection 45 engages with the locking hole 35, and thereafter the locking arm 40 recovers its original posture from its bent state by the moderate restoring elastic force stored therein.

When such an engaged state is released, the locking arm 40 is intentionally bent to carry out the release. Thus, the connector constructed in the auxiliary machine module Z such as the camera module Z can be easily quickly coupled with or separated from the mating connector 10 attached to the wiring harness 4.

In the terminal receiving chamber of the connector housing 11 made of the synthetic resin, a locking lance (not shown in the figure) is provided in order to easily securely fix the female terminal 8w. Since such a locking lance also needs a flexible characteristic, the connector housing 11 is advantageously made of the synthetic resin.

The synthetic resin that is adaptable to the injection molding and has a thermoplastic property is for example, polybutylene terephthalate resin (PBT), acrylonitrile butadiene styrene resin (ABS), polyamide resin (PA), and polypropylen resin (PP). A various type of filler may be added to the synthetic resin as the need arises.

Each part such as the camera case 3 to which the connector housing 33 is integrally formed, molded resin part 6 of the intermediate connector board 5, and the connector housing 11 to which the locking arm 40 and the locking lance are integrally formed, may be made of polybutylene terephthalate resin (PBT) and is excellent in terms of dimensional stability, mechanical strength stability, and stable electric performance. For example, PBT-H01 can be used as the polybutylene terephthalate resin (PBT). As for the molded resin part 6 of the intermediate connector board 5, a hot melt material of polyamide-base material may be used and the injection molding may be carried out.

The molded body such as the camera case 3, connector housing 11 or the molded resin part 6 of the intermediate connector board 5 may be subjected to a tumble polishing as the need arises after the molded body is taken out from the mold.

As shown in FIGS. 1-6, some of each corner of the camera 1, auxiliary machine board 2, camera case 3, molded resin part 6 of the intermediate connector board 5, and the connector housing 11 of the mating connector 10 is chamfered to prevent stress concentration from occurring at the corner of the part and to prevent a worker from being hurt with the corner of the part.

As the need arises, any type of additional part may be attached to the auxiliary machine module Z or the intermediate component 5. However, depending upon a portion where the auxiliary machine is used or mounted, the additional part such as the cover may be omitted.

Besides the camera module Z as described above, the present invention can also be applied to any type of auxiliary machine module such as one, which is used for an instrument panel or its surroundings.

The camera module according to the present invention can be used mainly for a passenger car or a large-size car such as a bus and can be mounted to a position on a vehicle, for example, a position at which a driver can hardly see, so that the module can further be used to assist for confirm a dead angle during traveling.

Further, in the event that the on-vehicle CCD camera 1 mounted to an outer position at the rear of a motor vehicle accidentally hits against something, for example, when the vehicle is moving back and accordingly that the CCD camera 1 has to be checked and repaired, since the on-vehicle CCD camera 1 to which the present invention is applied can be easily disassembled, therefore the damaged CCD camera 1 is easily disassembled, repaired and thereafter mounted again on the vehicle. Consequently, the CCD camera 1 to which the present invention is applied is preferably mounted to an outer position at the rear of a motor vehicle as a CCD camera 1 for confirming a field of view.

In the event that a damage takes place in the CCD camera 1 or the camera module Z, a check, disassembly and repair may be needed. The camera module Z according to the present invention can easily be assembled or disassembled, and accordingly has an advantage in terms of maintenance. Further, since the camera module Z can be easily disassembled, it can be easily recycled upon disposal thereof.

The aforementioned preferred embodiments are described to aid in understanding the present invention and variations may be made by one skilled in the art without departing from the spirit and scope of the present invention.

What is claimed is:

1. A connection structure between a terminal and a flexible printed circuit body comprising:
a base including a mounting hole for receiving a terminal and a locking hollow for fixing the terminal;
a flexible printed circuit body including a circuit conductor; and
the terminal including a first locking portion engaging with the locking hollow and a second locking portion fixed to the base putting the flexible printed circuit body therebetween,
wherein the terminal is inserted in the mounting hole through the circuit conductor so as to be electro-conductively connected to the circuit conductor.

2. The connection structure between a terminal and a flexible printed circuit body according to claim 1, wherein the first locking portion abuts against the locking hollow formed on the circumference of the mounting hole while the second locking portion abuts against the circuit conductor so that the terminal is fixed in the base.

3. The connection structure between a terminal and a flexible printed circuit body according to claim 1 or 2, wherein the first locking portion is a pair of projections while the second locking portion is a bent portion having a S-shape.

4. An auxiliary machine module comprising:
an auxiliary machine board which includes a terminal and is mounted on an auxiliary machine;
an intermediate component including: a first electric joint having a first terminal and a first base, in which the first terminal having first and second locking portions is mounted to the first base; a second electric joint having a second terminal and a second base, in which the second terminal having the first and second locking portions is mounted to the second base; and a flexible printed circuit body in which a circuit conductor connects the first terminal of the first electric joint to the second terminal of the second electric joint; and
a case,
wherein a connector housing is formed in the case to receive the first electric joint, the first electric joint is mounted in the connector housing so that a connector is formed in the case, and the auxiliary machine board is mounted to the case so that the terminal of the auxiliary machine board is coupled with the second terminal of the second electric joint.

5. The auxiliary machine module according to claim 4, wherein a mating connector including a terminal is coupled with the connector formed in the case having the first terminal so as to make an electrical connection.

6. The auxiliary machine module according to claim 4 or 5, wherein the auxiliary machine is a camera to be mounted on a motor vehicle.
